(19) United States
(12) Patent Application Publication
(10) Pub. No.: US 2008/0277741 A1
(43) Pub. Date: Nov. 13, 2008

(54) SEMICONDUCTOR DEVICE AND METHOD FOR MANUFACTURING THE SAME

(75) Inventor: Seon Yong CHA, Cheongju-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor, Inc., Ichon-shi (KR)

(21) Appl. No.: 11/765,670

(22) Filed: Jun. 20, 2007

(30) Foreign Application Priority Data
May 10, 2007 (KR) 10-2007-0045666

(51) Int. Cl. H01L 27/105; H01L 21/8239

(52) U.S. Cl. 257/401; 438/268; 257/E29.262; 257/E29.264; 257/E21.618; 257/E21.619; 257/E21.621; 257/E21.629

(57) ABSTRACT

A semiconductor device includes a semiconductor substrate; a source area, a channel area and a drain area vertically stacked on the semiconductor substrate; and a gate formed in both side walls of the stacked source area, channel area and drain area under interposition of a gate insulation layer.

### CROSS-REFERENCE TO RELATED APPLICATIONS

The present application claims priority to Korean patent application number 10-2007-0045666 filed on May 10, 2007, which is incorporated herein by reference in its entirety.

### BACKGROUND OF THE INVENTION

The present invention relates to a semiconductor device, and more particularly, to a semiconductor device having a floating body cell structure and a method for manufacturing the same.

The recent semiconductor industry has been directed towards improving the degree of integration of a semiconductor device and increasing the manufacturing yield. As an example, there has been proposed a semiconductor device having a floating body cell (hereinafter, referred to as FBC) structure.

The semiconductor device having the FBC structure can be made smaller than current capacitors for storing information and thus can produce a highly integrated device as compared with a conventional dynamic random access memory (DRAM) device.

The semiconductor device having the conventional FBC structure and an operation principle thereof will be roughly described hereinafter with reference to FIG. 1.

The semiconductor device having the FBC structure is realized in a silicon on insulator (SOI) wafer 100 in which a filled oxide layer 104 is interposed between a semiconductor substrate 102 and a silicon layer 106 for forming a device, and thus has a structure where a body 116 of a transistor corresponding to an area between a source area 112 and a drain area 114 is floated. Particularly, the semiconductor device having the FBC structure is not formed with a capacitor for storing an electric charge.

In the semiconductor device having the FBC structure, after a voltage is applied to a gate 110 through a word line WL which turns on a transistor, a voltage is applied to the drain area 114 through a bit line BL which generates a current. From the high electric field of the drain area 114 generated by the current, electrons collide with a silicon lattice thereby generating electrons and holes and the generated holes are accumulated in the floating body 116 between the source area 112 and the drain area 114.

Herein, the holes accumulated in the floating body 116 has an influence on a body bias of the transistor. Specifically, the body bias increases with an increase of holes and thus a threshold voltage of the transistor is lowered, and consequently a increased current is obtained for the same voltage.

FIG. 2 is a graph comparing currents in a state where holes are accumulated in the floating body and a state where holes are not accumulated in the floating body. The different currents (with and without accumulated holes in the floating body) in the semiconductor device having the FBC structure are assigned to logic “1” or logic “0” on to enable the device to operate as a memory.

Specifically, in the case of a writing operation, writing a logic “1” corresponds to a case where holes are generated by a hot carrier effect and accumulated in the floating body and writing a logic “0” corresponds to a case where a negative current is applied to the drain area through the bit line to remove the holes accumulated in the floating body. On the other hand, a reading operation is carried out by comparing a magnitude of a current after turning the word line on.

The semiconductor device having the FBC structure is operable without a capacitor, as opposed to a DRAM cell, and this will be more advantageous in a future micro process for manufacturing a highly integrated device.

However, in the semiconductor device having the conventional FBC structure, a SOI wafer is used so that each cell can independently store generated holes, but the cost for manufacturing the SOI wafer is as high as ten times that of a general silicon wafer.

In addition, because the semiconductor device having the FBC structure which has been proposed until now is realized by forming a planar type transistor on the SOI wafer, a cell size has been limited to 8F² and thus there has been a difficulty in reducing the cell size.

Furthermore, the semiconductor device having the FBC structure, like the conventional DRAM device, requires a refresh as its holes are depleted by a junction leakage current. However, it is necessary to increase a channel dose in order to prevent a punch-through between the source area and the drain area caused by the high integration of the semiconductor device and thus a refresh characteristic is expected to be lowered by an increase in the junction leakage current.

### BRIEF SUMMARY OF THE INVENTION

Embodiments of the present invention relate to a semiconductor device having a FBC structure which can reduce manufacturing costs, reduce cell size, improve refresh characteristics, and a method for manufacturing the same.

In one embodiment, a semiconductor device may include a semiconductor substrate; a source area, a channel area and a drain area vertically stacked on the semiconductor substrate; and a gate formed in both side walls of the stacked source area, channel area and drain area under interposition of a gate insulation layer.

The source area is formed in a linear type and the channel area and the drain area are formed in a pattern type.

The linear type source area is formed in a surface of the semiconductor substrate through a selective impurity ion implantation.

The source area further includes a portion formed in a pattern type in a boundary between the source area and the channel area.

The pattern type channel area and drain area are formed in a pillar shape.

The source area and the drain area are formed of an n-type impurity ion implantation layer and the channel area is formed of a p-type impurity ion implantation layer.

The semiconductor device may further include a halo ion implantation layer formed in an interface between the drain area and the channel area.

The semiconductor device may further include an interlayer insulation layer formed on the semiconductor substrate formed with the gate so as to expose the drain area; and a bit line formed on the interlayer insulation layer so as to be on contact with the exposed drain area.

In another embodiment, a method for manufacturing a semiconductor device may include forming a first ion implantation layer in a linear type in a surface of a semiconductor substrate; forming a silicon layer on the semiconductor substrate including the first ion implantation layer; forming a second ion implantation layer in a surface of the silicon layer; etching the silicon layer including the second ion implantation layer to form a source area, a channel area and a drain area which are vertically stacked; and forming a gate in both side walls of the vertically stacked source area, channel area and drain area under an interposition of a gate insulation layer.

The source area is formed in a linear type and the channel area and the drain area are formed in a pattern type.

The source area is formed by etching together some thickness of the first ion implantation layer.

The pattern type channel area and drain area are formed in a pillar shape.

The linear type source area is formed in the surface of the semiconductor substrate through a selective impurity ion implantation.

The source area and the drain area are formed of an n-type impurity ion implantation layer and the channel area is formed of a p-type impurity ion implantation layer.

The silicon layer is formed by an epitaxial silicon growth process.

The silicon layer is formed so as to be doped with a p-type impurity.

The forming of the gate includes forming sequentially the gate insulation layer and a gate conductive layer on the semiconductor substrate including the vertically stacked source area, channel area and drain area; and etching back the gate conductive layer so as to expose the gate insulation layer.

The method may further include, after forming the gate, forming a halo ion implantation layer in an interface between the drain area and the channel area.

The method may further include, after forming the gate, forming an interlayer insulation layer on the semiconductor substrate formed with the gate; etching the interlayer insulation layer to expose the drain area; and forming a bit line in contact with the exposed drain area on the interlayer insulation layer.

The method may further include, after exposing the drain area and before forming the bit line, forming a halo ion implantation layer in an interface between the drain area and the channel area.

### BRIEF DESCRIPTION OF THE DRAWINGS

FIG. 1 is a sectional view illustrating a conventional semiconductor device and an operation principle thereof.

FIG. 2 is a graph in which currents in a state that holes are accumulated in a floating body and in a state that holes are not accumulated in the floating body are compared.

FIG. 3 is a sectional view illustrating a semiconductor device according to an embodiment of the present invention.

FIGS. 4A to 4H are sectional views illustrating the process steps of a method for manufacturing the semiconductor package according to an embodiment of the present invention.

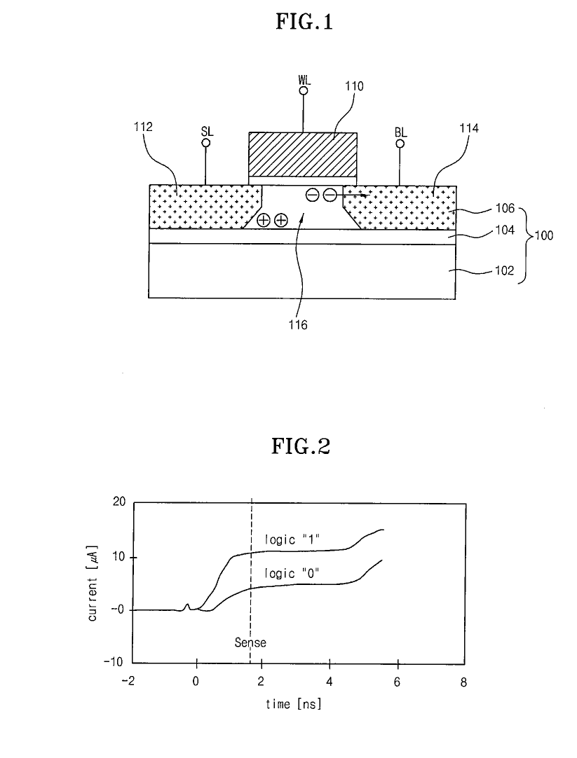

### DESCRIPTION OF SPECIFIC EMBODIMENTS

Embodiments of the present invention relate to a semiconductor device having a FBC structure, which uses a general silicon wafer and applies a vertical type transistor instead of using an existing SOI wafer and applying a planar transistor.

Therefore, in an embodiment of the present invention, the manufacturing cost can be reduced since a semiconductor device having a FBC structure, in which each cell can independently store the generated hole, can be manufactured using a general silicon wafer of which is about 1/10 the price of the SOI wafer.

Further, in an embodiment of the present invention the cell size can be reduced to 4F² by applying the vertical type transistor in comparison with the cell size of 8F² in the case of existing planar type transistors.

Also, in an embodiment of the present invention, by employing the vertical type transistor, a junction leakage current is reduced thereby improving the refresh characteristic and, because a gate is formed in both side walls of the channel area and the drain area of a pattern type having a pillar shape, the area of a gate insulation layer is increased thereby further improving the refresh characteristic.

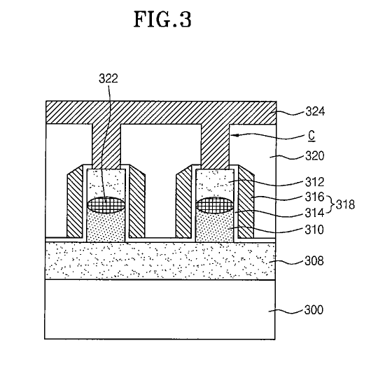

More specifically, FIG. 3 is a sectional view illustrating a semiconductor device in accordance with an embodiment of the present invention and the explanation to this follows hereinafter.

AS shown, a source area 308, a channel area 310 and a drain area 312 are vertically stacked on a p-type semiconductor substrate 300 and a gate 318 composed of a gate insulation layer 314 and a gate conductive layer 316 is formed on both side walls of the stacked channel area 310 and drain area 312.

The source area 308 and the drain area 312 are formed of an n-type impurity ion implantation layer and the channel area 310 is formed of a p-type impurity ion implantation layer. Particularly, the source area 310 is formed in a linear type on the p-type semiconductor substrate 300 through a selective impurity ion implantation and the channel area 310 and the drain area 312 are formed in a pattern type having a pillar shape on the linear type source area 308. The source area 308 is formed in a linear type on the semiconductor substrate 300 and may be further formed in a pattern type below the channel area 310 as well.

A halo ion implantation layer 322 may be further formed in an interface between the drain area 312 and the channel area 310. The halo ion implantation layer 322 is an element for generating more hot carriers which can increase a writing speed of a semiconductor device having a FBC structure. In other words, because the halo ion implantation layer 322 not only serves to prevent a punch-through but also serves to selectively increase an electric field of the drain area 312 and to prevent an increase in junction leakage current of the source area 308, it is possible to increase the writing speed of a semiconductor device having a FBC structure.

The above mentioned semiconductor device having a FBC structure according to the present invention can be manufactured without using an expensive SOI wafer and thus manufacturing cost can be reduced. Further, in the semiconductor device having a FBC structure according to the present invention, since the vertical type transistor including the vertically stacked source area 308, channel area 310 and drain area 312 is formed, the cell size can be reduced and the junction leakage current is reduced thereby improving the refresh characteristic. Furthermore, in the semiconductor device having a FBC structure according to the present invention, since the halo ion implantation layer 322 is formed in the interface between the drain area 312 and the channel area 310, the generation of the hot carrier is increased and thus the writing speed of the semiconductor device can be increased.

In FIG. 3, a reference symbols C, 320 and 324, which are not explained, denote a contact hole, an interlayer insulation layer and a bit line, respectively.

Hereinafter, a method for manufacturing the semiconductor device having the FBC structure in accordance with an embodiment of the present invention will be described with reference to the attached drawings.

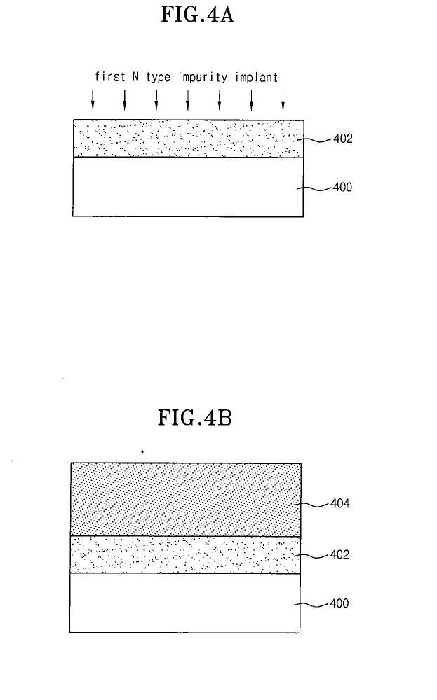

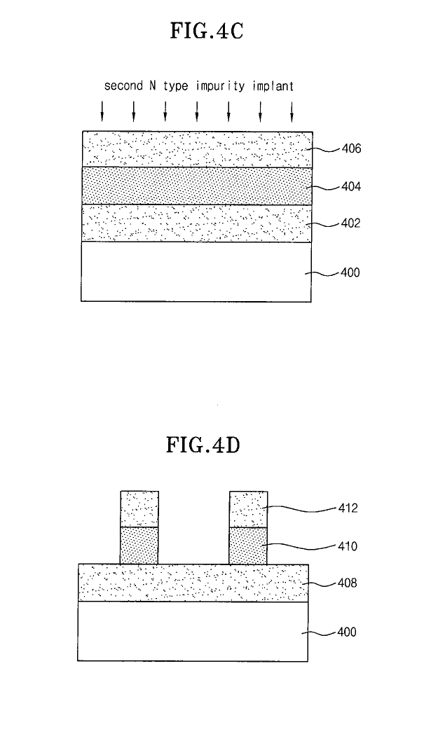

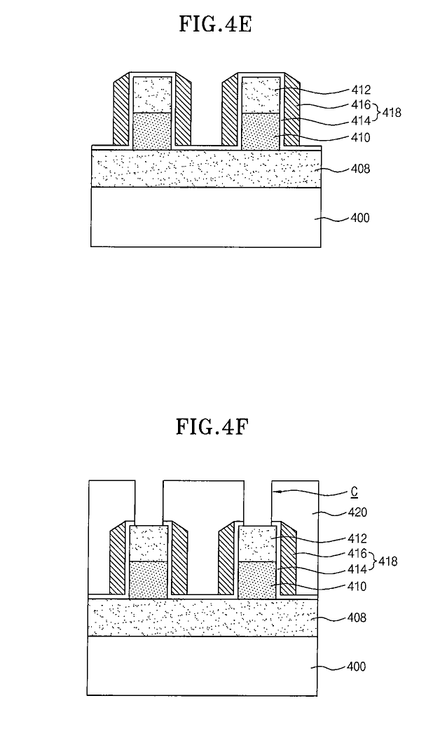

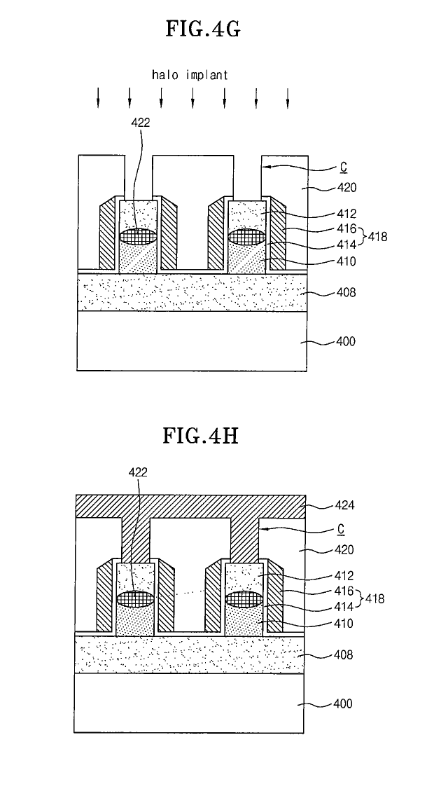

Referring to FIG. 4A, a first n-type impurity ion implantation process is carried out into the p-type semiconductor substrate 400 thereby forming an n-type first ion implantation layer 402 in a surface of the p-type semiconductor substrate 400. The first ion implantation layer 402 is formed in a linear type in the surface of the p-type semiconductor substrate 400 through a selective impurity ion implantation process.

Referring to FIG. 4B, a silicon layer 404 is formed on the p-type semiconductor substrate 400 and the n-type first ion implantation layer 402. The silicon layer 404 is formed through an epitaxial silicon growth process, at this time, a p-type impurity may be doped in the silicon layer 404.

Referring to FIG. 4C, a second n-type impurity ion implantation process is carried out into the silicon layer 404 doped with the p-type impurity thereby forming an n-type second ion implantation layer 406 in a surface of the silicon layer 404. As a result, the n-type first ion implantation layer 402, the p-type silicon layer 404 and the n-type second ion implantation layer 402 are sequentially stacked on the p-type semiconductor substrate 400.

Referring to FIG. 4D, the silicon layer including the second ion implantation layer is etched, thereby forming the source area 408, the channel area 410 and the drain area 412 which are vertically stacked on the semiconductor substrate 400. In other words, the n-type first ion implantation layer becomes the source area 408, the p-type silicon layer becomes the channel area 410 and the n-type second ion implantation layer becomes the drain area 412.

The source area 408 is formed in a linear type and the channel area 410 and the drain area 412 are formed in a pattern type having a pillar shape. At this time, it may be possible that some thickness of the first ion implantation layer is etched together when etching the silicon layer including the second ion implantation layer and thus the source area 408 is formed in a linear type on the semiconductor substrate 400 and in a pattern type below the channel area 410.

Referring to FIG. 4E, the gate insulation layer 414 and the gate conductive layer 416 are sequentially deposited on the semiconductor substrate 400 including the vertically stacked source area 408, channel area 410 and drain area 412. The gate insulation layer 414 is formed of an oxide layer and the gate conductive layer 416 is formed of a polysilicon layer. After that, the gate conductive layer 416 is etched back so as to expose the gate insulation layer 414 thereby forming the gate 418 on both side walls of the stacked channel area 410 and drain area 412.

In accordance with the present invention, after forming the source area 408, the channel area 410 and the drain area 418, the gate is formed on both sides of the vertical type transistor, thereby enabling the manufacturing of the semiconductor device having a FBC structure. In addition, by applying the vertical type transistor when manufacturing the semiconductor device having a FBC structure, the cell size can be reduced as compared with the conventional case in which a planar transistor is applied. Furthermore, since it is possible to use a general silicon wafer instead of a high priced SOI wafer, a manufacturing cost can be reduced as compared with a conventional semiconductor device using the SOI wafer.

Referring to FIG. 4F, the interlayer insulation layer 420 is deposited on the semiconductor substrate 400 including the gate 418 so as to cover the gate 418. After that, the interlayer insulation layer 420 and the gate insulation layer 414 are etched until the drain area 412 is exposed, thereby forming the contact hole C.

Referring to FIG. 4G, a halo ion implantation process is carried out into the semiconductor substrate 400 formed with the contact hole C thereby forming the halo ion implantation layer 422 in the interface between the drain area 412 and the channel area 410. The halo ion implantation layer 422 serves to generate more hot carriers and thus it is possible to increase the writing speed of the semiconductor device having a FBC structure in accordance with the present invention.

In other words, because the halo ion implantation layer 422 not only prevents the punch-through but also serves to selectively increase an electric field of the drain area 412 and to prevent an increase in junction leakage current of the source area 408, it is possible to increase the writing speed of the semiconductor device having a FBC structure according to the present invention.

Referring to FIG. 4H, a conductive layer for a bit line is deposited on the resultant product of the semiconductor substrate 400 formed with the halo ion implantation layer 422 so as to fill the contact hole C. After that, the conductive layer for a bit line is etched to form a bit line 424 which is in contact with the drain area 412.

After that, though not shown, a series of known follow up processes are sequentially proceeded, thereby creating the semiconductor device having the FBC structure according to an embodiment of the present invention.

As described above, in the present invention, because a semiconductor device having a FBC structure is realized using a general silicon wafer, which is relatively inexpensive as compared to a conventional SOI wafer, a manufacturing cost can be reduced.

Furthermore, in the present invention, because a semiconductor device having a FBC structure is manufactured by applying a vertical type transistor, a cell size can be reduced from 8F² to 4F² as compared with using a planar type transistor, and thus it is advantageous in manufacturing of a highly integrated device.

Also, in the present invention, a junction leakage current is reduced and thus a refresh characteristic can be improved, thereby improving device properties and reliability.

In addition, in the present invention, since source area is formed in a linear type, it is not necessary to form separately a bit line which is in contact with the source area, thereby simplifying a process and layout of a semiconductor device.

In addition, in the present invention, because a gate is formed in both side walls of pillar shaped pattern type channel area and drain area, a capacitance can be increased as an area of a gate insulation layer is increased compared with a conventional art, and thus a generation amount of holes is increased, thereby improving a refresh characteristic.

Although embodiments of the present invention has been described for illustrative purposes, those skilled in the art will appreciate that various modifications, additions and substitutions are possible, without departing from the scope and the spirit of the invention as disclosed in the accompanying claims.

1. A semiconductor device comprising:
a substrate;
a first doped region provided over the substrate;
a channel region provided over the first doped region, the channel region defining a plurality of side walls;
a second doped region provided over the channel region; and
a gate extending vertically against at least one side wall defined by the channel region.

2. The semiconductor device according to claim 1, wherein a gate insulation layer is provided between the gate and the channel region, wherein the first doped region is a linear type and the channel region and the second doped region are a pattern type.

3. The semiconductor device according to claim 2, wherein the first doped region is formed on an upper surface of the semiconductor substrate through a selective impurity ion implantation, wherein the first doped region is a doped region for a plurality of cells.

4. The semiconductor device according to claim 3, wherein the first doped region further includes a portion formed in a pattern type in a boundary between the first doped region and the channel region.

5. The semiconductor device according to claim 2, wherein the channel region and second doped region have a pillar shape.

6. The semiconductor device according to claim 1, wherein the first and second doped regions are n-type regions and the channel region is a p-type region.

7. The semiconductor device according to claim 1, further comprising a halo ion implantation layer formed in an interface between the second doped region and the channel region.

8. The semiconductor device according to claim 1, further comprising:
an interlayer insulation layer formed over the semiconductor substrate so as to expose the second doped region; and
a bit line formed on the interlayer insulation layer so as to be on contact with the exposed second doped region,
wherein the first doped region is a source region, and the second doped region is a drain region.

9. A method for manufacturing a semiconductor device, the method comprising:
forming a first ion implantation layer on a surface of a semiconductor substrate;
forming a silicon layer on the semiconductor substrate including the first ion implantation layer;
forming a second ion implantation layer on a surface of the silicon layer;
etching the silicon layer including the second ion implantation layer to form a source area, a channel area and a drain area which are vertically stacked; and
forming a gate in both side walls of the vertically stacked source area, channel area and drain area.

10. The method for manufacturing a semiconductor device according to claim 9, wherein the source area is formed in a linear type and the channel area and the drain area are formed in a pattern type.

11. The method for manufacturing a semiconductor device according to claim 10, the source area is formed by etching the first ion implantation layer.

12. The method for manufacturing a semiconductor device according to claim 10, wherein the pattern type channel area and drain area are formed in a pillar shape.

13. The method for manufacturing a semiconductor device according to claim 10, wherein the source area is formed on the surface of the semiconductor substrate through a selective impurity ion implantation.

14. The method for manufacturing a semiconductor device according to claim 9, wherein the source area and the drain area are f n-type regions and the channel area is a p-type region.

15. The method for manufacturing a semiconductor device according to claim 9, wherein the silicon layer is formed by an epitaxial silicon growth process.

16. The method for manufacturing a semiconductor device according to claim 15, wherein the silicon layer is formed so as to be doped with a p-type impurity.

17. The method for manufacturing a semiconductor device according to claim 9, wherein the forming of the gate comprises:
forming sequentially the gate insulation layer and a gate conductive layer over the semiconductor substrate including the vertically stacked source area, channel area and drain area; and
etching back the gate conductive layer so as to expose the gate insulation layer.

18. The method for manufacturing a semiconductor device according to claim 9, further comprising, after forming the gate, forming a halo ion implantation layer in an interface between the drain area and the channel area.

19. The method for manufacturing a semiconductor device according to claim 9, further comprising, after forming the gate,
forming an interlayer insulation layer over the semiconductor substrate formed with the gate;
etching the interlayer insulation layer to expose the drain area; and
forming a bit line that is configured to contact the exposed drain area.

20. The method for manufacturing a semiconductor device according to claim 19, further comprising, after exposing the drain area and before forming the bit line, forming a halo ion implantation layer in an interface between the drain area and the channel area.
